(19) United States
(12) Patent Application Publication
(10) Pub. No.: US 2024/0044388 A1
(43) Pub. Date: Feb. 8, 2024

(54) Compliant Structure

(71) Applicant: Technische Universiteit Delft, Delft (NL)

(72) Inventors: Thijs Willem Albert Blad, Delft (NL); Justus Laurens Herder, Delft (NL)

(21) Appl. No.: 18/490,167

(22) Filed: Oct. 19, 2023

Related U.S. Application Data
(63) Continuation of application No. PCT/NL2022/050161, filed on Mar. 24, 2022.

(30) Foreign Application Priority Data
Apr. 21, 2021 (NL) 2028025

(51) Int. Cl. F16F 1/02; G01P 15/09; G01L 1/16; G01V 1/18; G01P 1/00; B81B 3/00; H02N 2/18; H04R 17/02

(52) U.S. Cl. CPC F16F 1/027; G01P 15/09; G01L 1/16; G01V 1/181; G01P 1/00; B81B 3/007; H02N 2/186; H04R 17/02; B81B 2203/0118; B81B 2203/053; H04R 2201/003

(57) ABSTRACT

A compliant structure including a frame and a shuttle distant from the frame mounted on a cantilever that is supported by the frame. The cantilever and shuttle together are movable transversely to and out of a plane of the frame. The structure also includes one or more flexures that connect the cantilever with the frame. The cantilever includes a body at least in part extending in a first direction which points to the shuttle. The one or more flexures connect to the shuttle and/or to the cantilever in the vicinity of the shuttle. The flexures are oriented in a second direction, which second direction is generally transverse with respect to the first direction.

### CROSS-REFERENCE TO RELATED APPLICATIONS

This application is a continuation of International Application No. PCT/NL2022/050161, entitled “A Compliant Structure”, filed Mar. 24, 2022, which claims priority to Netherlands Patent Application No. 2028025, entitled “A Compliant Structure”, filed Apr. 21, 2021, and the specifications and claims thereof are incorporated herein by reference.

### BACKGROUND OF THE INVENTION

### Field of the Invention

The invention relates to a compliant structure comprising a frame, a shuttle distant from the frame and mounted on a cantilever that is supported by the frame, wherein the cantilever with the shuttle is movable transversely to and out of a plane of the frame, and wherein the structure further comprises one or more flexures that connect the cantilever with the frame.

### Background Art

WO2017086785A1 describes an ortho-planar spring comprising a frame and a shuttle that is perpendicularly movable with respect to the frame, wherein flexible members connect the shuttle to the frame, and wherein in an unloaded condition the frame, the flexible members and the shuttle provide the spring with a flat configuration.

US2013/0038175 describes a compliant structure comprising a frame, a shuttle distant from the frame mounted on a cantilever that is supported by the frame, wherein the cantilever with the shuttle is movable transversely to and out of a plane of the frame, and wherein the structure further comprises one or more flexures that connect the cantilever with the frame, wherein the cantilever has a body at least in part extending in a first direction which points to the shuttle, and that the one or more flexures connect to the shuttle and/or to the cantilever in the vicinity of the shuttle, wherein the flexures are oriented in a second direction, which second direction is generally transversely with respect to the first direction.

### BRIEF SUMMARY OF THE INVENTION

Embodiments of the present invention are directed to a compliant structure comprise flexures, the flexures being preloaded causing the flexures to buckle so as to provide a selectable stiffness to the cantilever and to provide the cantilever with a preferential position out of the plane of the frame.

The cantilever may be straight, but it may also have another configuration, such as zigzag shape or a tapered shape.

With the structure of the invention, the Eigen frequency of the structure can be remarkably reduced and the mechanical efficiency and the range of motion of the cantilever can be improved. It is also possible that the out of plane stiffness of the cantilever can be fully compensated such that static balancing can be achieved.

Advantageously the manufacturing cost of the structure of the invention and be kept low by implementing the structure as a unitary micro-electromechanical system (MEMS) structure.

Preferably the cantilever of the compliant structure of the invention is piezoelectric. Motion of the cantilever translates then to electric power, which makes possible that the structure of the invention can be used for energy harvesting. However also other applications are feasible such as use as an oscillator, an accelerometer, a geophone, a microphone, a force sensor.

Beneficially the frame is clamped between a top package element and a bottom package element so as to provide the required sturdiness to the construction.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more embodiments of the invention and are not to be construed as limiting the invention. In the drawings:

FIG. 1A and FIG. 1B are illustrations showing schematic drawings of the structure of a compliant structure in an isometric view without nonessential parts according to an embodiment of the present invention;

FIG. 2 is an illustration showing a top view of the structure of a compliant structure according to an embodiment of the present invention;

FIG. 3 is an illustration showing an exploded view of a compliant structure according to an embodiment of the present invention;

FIG. 4A and FIG. 4B are illustrations showing a compliant structure in an assembled state according to an embodiment of the present invention;

FIG. 5A and FIG. 5B are illustrations showing a compliant structure in which the cantilever has a zigzag shape according to an embodiment of the present invention; and

FIG. 6 is an illustration showing a compliant structure with a variation in the orientation of the flexures according to an embodiment of the present invention.

### DETAILED DESCRIPTION OF THE INVENTION

Whenever in the figures the same reference numerals are applied, these numerals refer to the same parts.

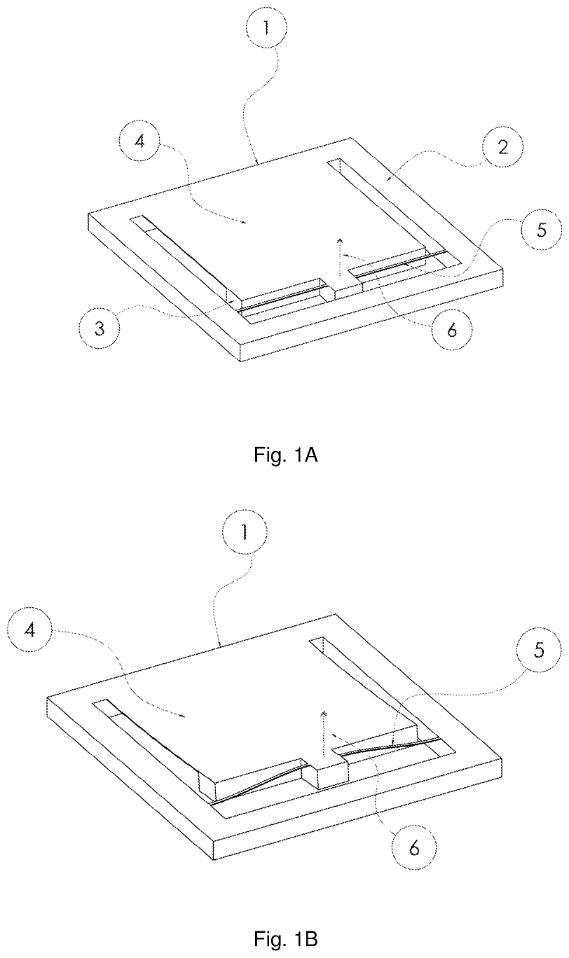

FIG. 1A shows structure 1 of the invention in an unloaded situation, whereas FIG. 1B shows the structure of the invention in a loaded situation.

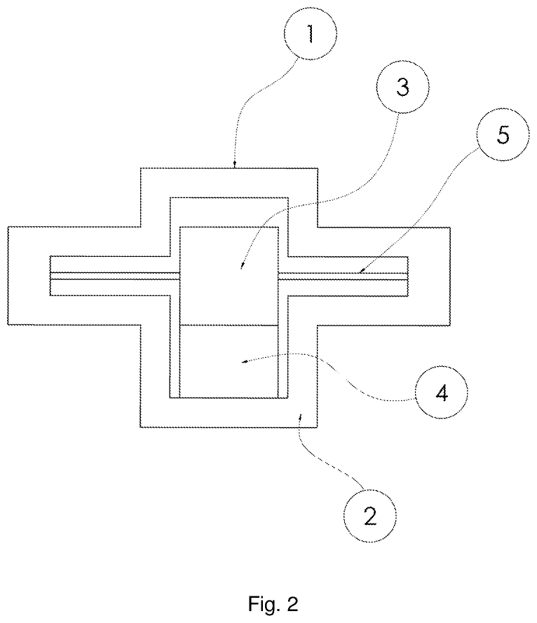

Structure 1 comprises frame 2, shuttle 3 distant from frame 2 mounted on cantilever 4 that is supported by frame 2, wherein cantilever 4 with shuttle 3 is movable transversely out of a plane of frame 2, as is depicted in FIG. 1A and FIG. 1B. Structure 1 further comprises one or more flexures 5 that connect cantilever 4 with frame 2, resulting in a degree of freedom out of plane of frame 2 as depicted by axis 6 shown in FIG. 1B. One thing and another is also shown in FIG. 2, wherein the degree of freedom is of course not shown since that is perpendicular to the sheet of the drawing.

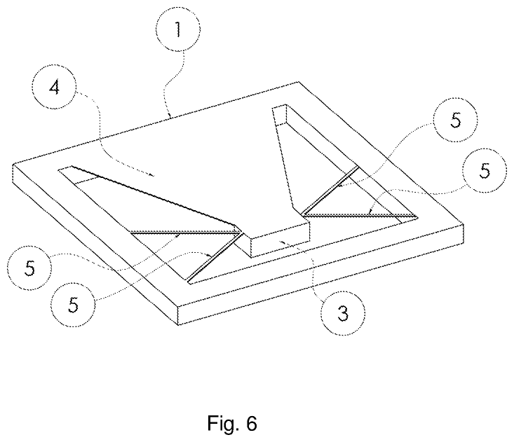

As will be understood from FIGS. 1A/1B and 2, cantilever 4 has a body extending in a first direction away from where cantilever 4 is supported by frame 2 and pointing to shuttle 3. The one or more flexures 5 connect to shuttle 3—as may be best seen in FIG. 2—and/or to the cantilever in the vicinity of the shuttle, wherein flexures 5 are oriented in a second direction, which second direction is in this embodiment generally at right angles with respect to the first direction of the cantilever body. A generally transverse orientation of the second direction with respect to the first direction that is not exactly at right angles is however also possible. An example thereof is shown in FIG. 6.

Flexures 5 are preloaded causing the flexures to buckle and to provide a selectable stiffness to cantilever 4 and to provide cantilever 4 with a preferential position out of the plane of frame 2. Accordingly, cantilever 4 represents a bi-stable system.

The structure of the invention is preferably a unitary MEMS structure, but it is also possible to construe the structure with 3D printing and laser micro-machining.

For particular applications it is preferable that the cantilever is piezoelectric. This makes the structure particularly suitable as a micro-energy harvester.

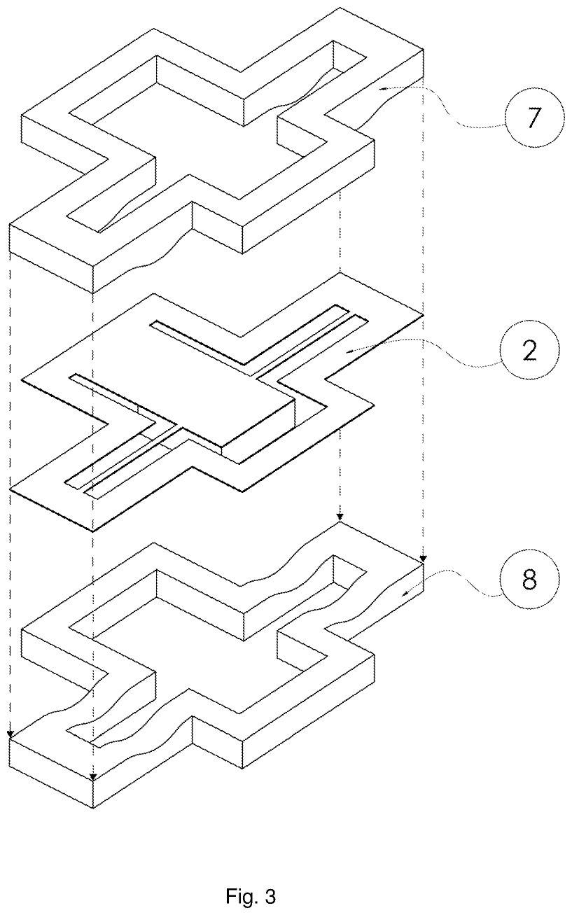

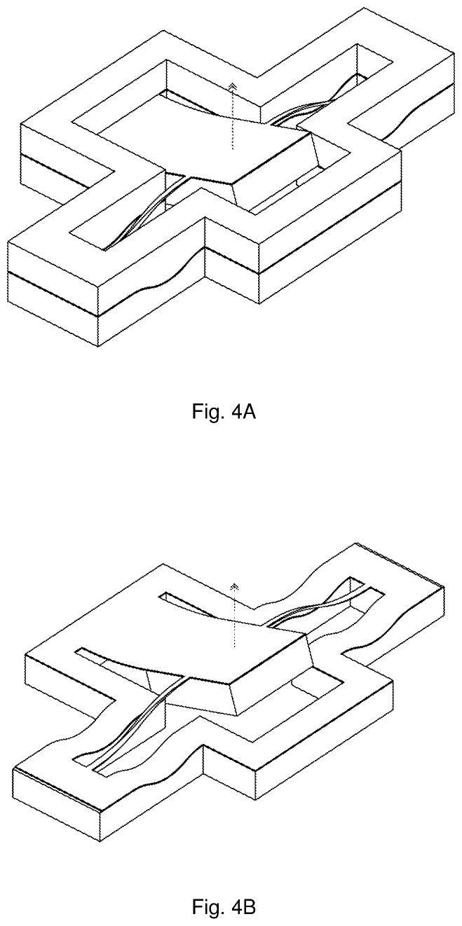

For practical applications it is desirable that frame 2 is clamped between top package element 7 and bottom package element 8. An exploded view thereof is provided by FIG. 3, whereas same in assembled state is shown in FIG. 4A. FIG. 4B corresponds with FIG. 4A without top package element 7.

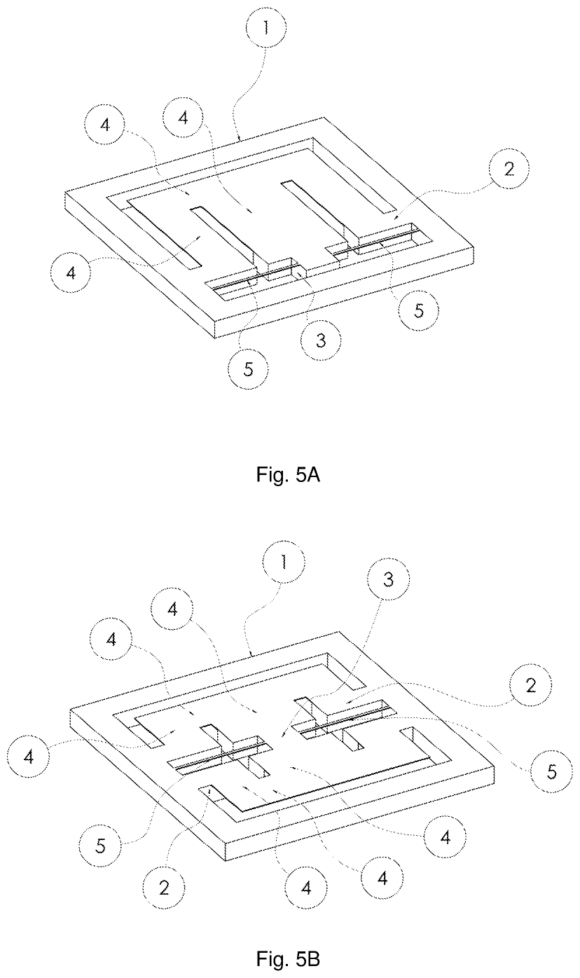

FIG. 5A provides a first example of the structure of the invention wherein cantilever 4 has a zigzag shape, as opposed to the straight configuration of cantilever 4 as depicted in FIGS. 1-4. Also, in this embodiment shuttle 3 is mounted on cantilever 4 distant from frame 2, wherein cantilever 4 is supported by frame 2. Cantilever 4 with shuttle 3 is movable transversely to and out of a plane of frame 2, and structure 1 further comprises one or more flexures 5 that connect cantilever 4 with frame 2. Cantilever 4 has a zig-zag shaped body which at least in part extends eventually in a first direction which points to shuttle 3. Flexures 5 connect to shuttle 3, but could also connect to cantilever 4 in the vicinity of shuttle 3. Again, flexures 5 are oriented in a second direction that is generally transversely with respect to the first direction, which points to shuttle 3.

FIG. 5B shows a second example of the structure of the invention wherein cantilever 4 has a zigzag shape body which at least in part eventually extends in a first direction which points to shuttle 3. In this second example there is a zigzag shaped ‘double’ cantilever which is mirrored on opposite sides of flexures 5. Also, in this example flexures 5 are oriented in a second direction that is generally transversely with respect to the first direction of ‘double’ cantilever 4, which points to shuttle 3.

FIG. 6 depicts the situation that the structure of the invention is embodied with flexures 5 that are not exactly at right angles but that are oriented in a second direction, which second direction is generally transversely with respect to the first direction in which cantilever 4, which in this case is tapered, extends from the point where cantilever 4 connects to frame 2.

Although the invention has been discussed in the foregoing with reference to an exemplary embodiment of the structure of the invention, the invention is not restricted to this particular embodiment which can be varied in many ways without departing from the invention. The discussed exemplary embodiment shall therefore not be used to construe the appended claims strictly in accordance therewith. On the contrary the embodiment is merely intended to explain the wording of the appended claims without intent to limit the claims to this exemplary embodiment. The scope of protection of the invention shall therefore be construed in accordance with the appended claims only, wherein a possible ambiguity in the wording of the claims shall be resolved using this exemplary embodiment.

Embodiments of the present invention can include every combination of features that are disclosed herein independently from each other. Although the invention has been described in detail with particular reference to the disclosed embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference. Unless specifically stated as being “essential” above, none of the various components or the interrelationship thereof are essential to the operation of the invention. Rather, desirable results can be achieved by substituting various components and/or reconfiguration of their relationships with one another. The terms, “a”, “an”, “the”, and “said” mean “one or more” unless context explicitly dictates otherwise.

1. A compliant structure comprising:
a frame;
a shuttle distant from the frame mounted on a cantilever that is supported by the frame,
wherein the cantilever with the shuttle is movable transversely to and out of a plane of the frame; and
one or more flexures that connect the cantilever with the frame, wherein the cantilever comprises a body at least in part extending in a first direction which points to the shuttle, and the one or more flexures connect to the shuttle and/or to the cantilever in the vicinity of the shuttle, wherein the flexures are oriented in a second direction, which second direction is generally transverse with respect to the first direction, and wherein the flexures are preloaded causing the flexures to buckle so as to provide a selectable stiffness to the cantilever and to provide the cantilever with a preferential position out of the plane of the frame.

2. The compliant structure of claim 1, wherein the flexures are oriented in a second direction that is at right angles with the first direction.

3. The compliant structure of claim 1, wherein the structure is a unitary MEMS structure.

4. The compliant structure of claim 1, wherein the cantilever is piezoelectric.

5. The compliant structure of claim 1, wherein the frame is clamped between a top package element and a bottom package element.

6. The compliant structure of claim 1, wherein the structure is embodied as an energy harvester.

7. The compliant structure of claim 1, wherein the structure is embodied as an oscillator.

8. The compliant structure of claim 1, wherein the structure is embodied as an accelerometer.

9. The compliant structure of claim 1, wherein the structure is embodied as a geophone.

10. The compliant structure of claim 1, wherein the structure is embodied as a microphone.

11. The compliant structure of claim 1, wherein the structure is embodied as a force sensor.
